(19) United States
(12) Patent Application Publication
(10) Pub. No.: US 2021/0096614 A1
(43) Pub. Date: Apr. 1, 2021

(54) MOTHERBOARD AND DETACHABLE MODULE

(71) Applicant: ASUSTEK COMPUTER INC., Taipei City (TW)

(72) Inventors: Chung-Lun HSIEH, Taipei City (TW); Wei-Chia LIAO, Taipei City (TW)

(21) Appl. No.: 17/023,420

(22) Filed: Sep. 17, 2020

(30) Foreign Application Priority Data
Sep. 27, 2019 (CN) 201910923131.X

(51) Int. Cl. G06F 1/18; H05K 7/14; G06F 13/40

(52) U.S. Cl. CPC G06F 1/184; G06F 13/409; H05K 7/1431

(57) ABSTRACT

A motherboard, comprises a signal transmitting terminal and a plurality of connectors connected to the signal transmitting terminal, respectively. Each of the connectors supports a plurality of connection specifications for assembling a detachable module. The detachable module includes a golden finger connecting member and an I/O port.

### CROSS-REFERENCE TO RELATED APPLICATION

This application claims the priority benefit of China application serial No. 201910923131.X, filed on Sep. 27, 2019. The entirety of the above-mentioned patent application is hereby incorporated by reference herein and made a part of specification.

### BACKGROUND OF THE INVENTION

### Field of the Invention

The invention relates to a motherboard.

### Description of the Related Art

A motherboard of a computer usually includes an interface module for connecting with external electronic device. The input/output interfaces (I/O ports) include USB I/O ports, LAN I/O ports, WiFi I/O ports. The I/O ports are respectively disposed at openings of a computer housing for plugs being inserted. Conventionally, the I/O ports are soldered on the motherboard. The position of the I/O ports is constant. As a result, when the I/O port is damaged, it is not easily to be repaired or replaced. Furthermore, when the number or the type of the I/O port doesn't meet users' requirements, (for example, compare to the LAN I/O port, users might use USB more often and the USB I/O ports needs more), users cannot replace the I/O ports on the motherboard by their own. Consequently, it is rather inconvenient, and the idle I/O port cannot be utilized effectively.

### BRIEF SUMMARY OF THE INVENTION

A motherboard is provided in the disclosure. The motherboard comprises a signal transmitting terminal and a plurality of connectors connected to the signal transmitting terminal. Each of the connectors supports a plurality of connection specifications and assembled as a detachable module, and the detachable module includes a golden finger connecting member and an I/O port.

A detachable module is provided in the disclosure. The detachable module is configured to be assembled onto a motherboard. The motherboard includes a signal transmitting terminal and a plurality of connectors connected to the signal transmitting terminal. Each of the connectors supports a plurality of connection specifications for assembling a detachable module. The detachable module comprises a golden finger connecting member and an I/O port.

### BRIEF DESCRIPTION OF THE DRAWINGS

FIG. 1 is a schematic diagram showing a motherboard and a detachable module according to an embodiment of the disclosure,

FIG. 2A is an exploded view showing a detachable module according to an embodiment of the disclosure,

FIG. 2B is an exploded view showing a detachable module according to an embodiment of the disclosure,

FIG. 2C is an exploded view showing a control chip of a detachable module according to an embodiment of the disclosure,

FIG. 3A is a schematic diagram view showing an operation principle of a control chip of a detachable module according to an embodiment of the disclosure,

FIG. 3B is a schematic diagram showing an operation principle of a control chip of a detachable module according to an embodiment of the disclosure,

FIG. 4A is a side view showing a detachable module is assembled to a motherboard according to an embodiment of the disclosure, and

FIG. 4B is a bottom view showing a detachable module is assembled to a motherboard according to an embodiment of the disclosure.

### DETAILED DESCRIPTION OF THE EMBODIMENTS

The operation principles of a motherboard and a detachable module will be described with reference to embodiments hereinafter.

In the present disclosure, the term “fixed” or “fastened” is defined as that two elements are fixedly disposed together, and they do not rotate or move relative to each other. However, the two elements may be detached or removed when a particular force applies thereon. The term “connected” is defined as a fixed relationship or a pivotal relationship between two elements. Furthermore, the terms “connected”, “electrically connected” or “coupled” mean a direct connection or an indirect connection unless specifically emphasized. The terms “comprising”, “including”, “having”, and the like in this disclosure are open-ended.

The terms “when” includes before, current, and after. In addition, when the term “or” is used between a number of functions (or elements), it is meant that the functions (or elements) can be present independently, and the functions (or elements) also may be included at the same time.

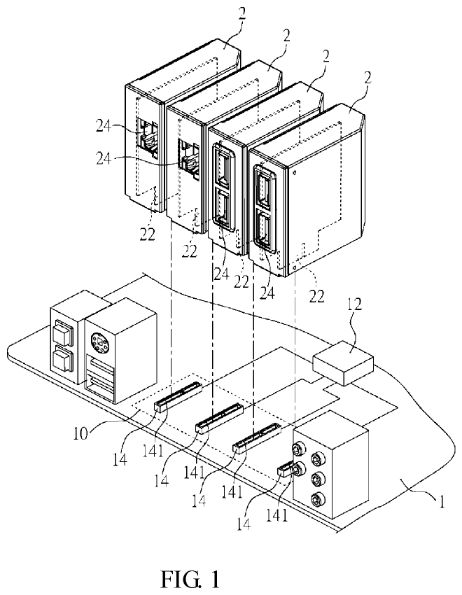

FIG. 1 is a schematic diagram showing a motherboard and a detachable module according to an embodiment of the disclosure. As shown in FIG. 1, a motherboard 1 includes a module setting area 10, a signal transmitting terminal 12, and a plurality of connectors 14. The connectors 14 are disposed at the module setting area 10. Each connector 14 supports a plurality of connection specifications and configured to connect to a detachable module 2. The detachable module 2 includes a golden finger connecting member 22 and an I/O port 24.

The connectors 14 are respectively connected to the signal transmitting terminal 12. The signal transmitting terminal 12 is configured to transmit signals to each of the connectors 14. The connectors 14 are configured to be connected to the detachable module 2. In an embodiment, each connector 14 includes a connector slot 141. The connector slot 141 includes a plurality of pins. The golden finger connecting member 22 includes pins corresponding to the connector slot 141.

The detachable module 2 is configured to insert and fasten to the connector slots 141 via the golden finger connecting members 22. In an embodiment, each connector 14 is connected with a detachable module 2. In an embodiment, the connectors 14 are next generation form factor (NGFF) connectors, such as NGFF B-KEY connectors, NGFF E-KEY connectors, NGFF M-KEY connectors, or M2 specification connectors, which is not limited herein.

Each detachable module 2 includes at least one I/O port 24. In an embodiment, the I/O port 24 is a slot member for connecting with a plug.

In an embodiment, the I/O ports 24 of the detachable module 2 support various connection specifications. In an embodiment, the I/O port 24 support USB specifications and is a USB I/O port. Further, the I/O port 24 is a LAN I/O port, a WiFi I/O port, or an audio signal I/O port, which is not limited herein. In an embodiment, the detachable module 2 includes two or more I/O ports 24. In an embodiment, the detachable module 2 includes two USB I/O ports.

In an embodiment, each of the connectors 14 supports different connection specifications. In other words, the connector 14 is available for different detachable modules 2. As a result, it brings increased functionality without considering whether the detachable modules 2 mutually include the same connection specification or not.

The motherboard 1 is applied to different electronic devices, such as a desktop computer, a notebook computer, or a tablet computer, which is not limited herein. In the embodiment, the motherboard 1 is applied to a desktop computer. The module setting area 10 is a setting area for I/O ports. The I/O ports are slots used for connected with external electronic devices. The module setting area 10 is usually configured at a peripheral area of the motherboard 1, and then the slots are easily configured thereon. When the motherboard 1 is assembled in the desktop computer, the module setting area 10 is positioned near a casing of the computer. The casing includes openings corresponds to I/O ports, and the I/O ports are exposed at the openings.

Conventionally, the I/O ports are soldered at the module setting area, and thus they are not easily removed. In contrast, the connectors 14 are configured on the module setting area 10 in embodiments. The detachable module 2 includes the golden finger connecting members 22 corresponding to the connectors 14. The detachable module 2 is fastened with the connectors 14. Since the detachable module 2 is not soldered at the module setting area 10, the detachable module 2 is easily replaced according to requirements conveniently.

In an embodiment, the connectors 14 on the module setting area 10 support a same specification, such as NGFF KEY-E connectors, which is not limited herein. In an embodiment, the signal transmitting terminal 12 transmits an original signal of the same specification to every connector 14. In an embodiment, the original signal is a Universal Serial Bus (USB) signal or a Peripheral Component Interface Express (PCIe) signal, which is not limited herein. In an embodiment, the signal transmitting terminal 12 is a central processing unit (CPU), a south-bridge chip, or a frequency generator on the motherboard 1, which is not limited herein. In an embodiment, the connectors 14 receive power from the motherboard 1, which is not limited herein.

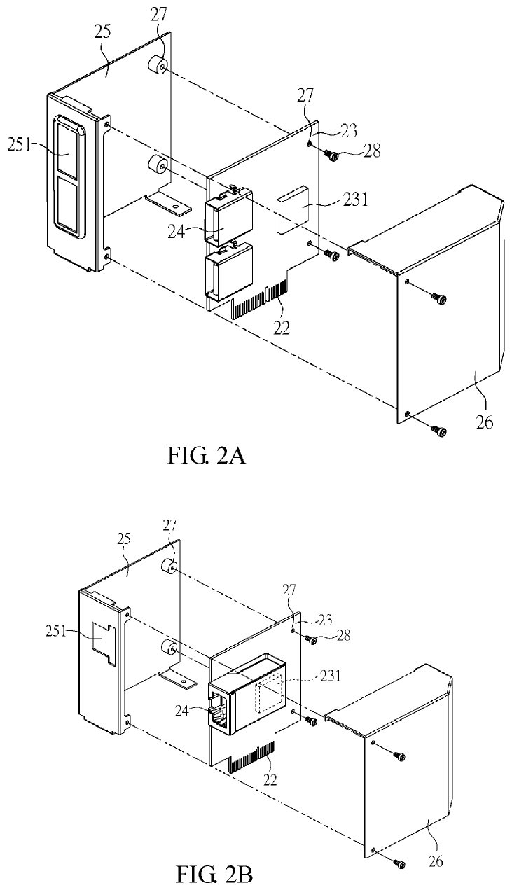

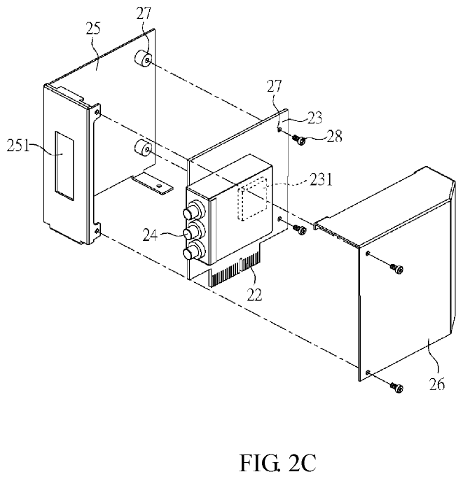

The detail of the detachable module 2 is shown in FIG. 2A, FIG. 2B, and FIG. 2C. Please also refer to FIG. 1.

FIG. 2A is an exploded view showing a detachable module according to an embodiment of the disclosure. In the embodiment, the specification of the detachable module 2 is USB. As shown in FIG. 2A, the detachable module 2 includes the golden finger connecting member 22, a circuit board 23, the I/O port 24, a first housing 25, and a second housing 26. The I/O port 24 is a USB I/O port (such as a USB slot). The number of the USB slot is not limited herein. A control chip 231 is configured on the circuit board 23. The first housing 25 includes an opening 251.

In an embodiment, the golden finger connecting member 22 is configured on the circuit board 23. For example, the golden finger connecting member 22 is configured at an edge of the circuit board 23. The I/O port 24 is configured on the circuit board 23 and electronically connected with the golden finger connecting member 22.

In an embodiment, the I/O port 24 is configured on the circuit board 23 and electronically connected with the golden finger connecting member 22 via layout wires, which is not limited herein. As shown in FIG. 1 and FIG. 2A, since the golden finger connecting member 22 is configured to be inserted into the connector slot 141 of the connectors 14, the pin number of the golden finger connecting member 22 is smaller than or equal to that of the connector slot 141. The position of the golden finger connecting member 22 corresponds to that of the connector slot 141.

As a result, the signal of the motherboard 1 is transmitted to the circuit board 23 via the connectors 14 and the golden finger connecting member 22, and then transmitted to the I/O port 24 via the control chip 231. Signals received at the I/O port 24 are transmitted to the motherboard 1 via the connectors 14 and the golden finger connecting member 22. In an embodiment, the control chip 231 is an integrated circuit which includes passive components such as resistors, capacitors and inductors.

In an embodiment, the circuit board 23 and the first housing 25 includes corresponding connecting components. In an embodiment, the circuit board 23 includes a screw hole 27. A screw 28 is screwed into the screw hole 27 of the first housing 25 to fix the circuit board 23 and the first housing 25. In an embodiment, the connecting components is an adhesion, soldered, or any component that connects the circuit board 23 and the first housing 25, which is not limited herein.

In an embodiment, the first housing 25 and the second housing 26 include corresponding connection components to assemble the first housing 25 and the second housing 26 together. For example, the first housing 25 and the second housing 26 includes the screw holes at corresponding positions, respectively. The screw passes through the corresponding positions to fix the first housing 25 and the second housing 26 together.

In an embodiment, when the circuit board 23 and the first housing 25 are assembled together, and the first housing 25 and the second housing 26 are assembled together, the first housing 25 and the second housing 26 covers most part of the circuit board 23, the golden finger connecting member 22 is exposed from the first housing 25 and the second housing 26. In an embodiment, when the circuit board 23 and the first housing 25 are assembled together, the position of the opening 251 of the first housing 25 corresponds to that of the I/O port 24, and then the I/O port 24 is exposed from the opening 251.

FIG. 2B is an exploded view showing a detachable module according to an embodiment of the disclosure. In the embodiment, the specification of the detachable module 2 is LAN. As shown in FIG. 2B, the detachable module 2 includes the golden finger connecting member 22, the circuit board 23, the I/O port 24, the first housing 25, and the second housing 26. The I/O port 24 is a LAN I/O port (such as a LAN slot). The number of the LAN slot is not limited herein. In an embodiment, the control chip 231 is configured on the circuit board 23, and the first housing 25 includes an opening 251.

Components in FIG. 2B are similar to those in FIG. 2A, which is not omitted herein.

FIG. 2C is a schematic diagram showing a control chip of the detachable module according to an embodiment of the disclosure. In the embodiment, the specification of the detachable module 2 is WiFi. As shown in FIG. 2C, the detachable module 2 includes the golden finger connecting member 22, the circuit board 23, the I/O port 24, the first housing 25, and the second housing 26. In the embodiment, the I/O port 24 is a WiFi I/O port. The number of the WiFi interface is not limited herein. In an embodiment, the control chip 231 is configured on the circuit board 23. The first housing 25 includes the opening 251.

Components in FIG. 2C are similar to those in FIG. 2A, which is omitted herein.

Please refer to FIG. 1, FIG. 2A, FIG. 2B, and FIG. 2C. In an embodiment, the connector 14 on the motherboard 1 is a NGFF KEY-E connector (such as a NGFF KEY-E 67P G/F 5.3H S/T connector). In an embodiment, some pins of the NGFF KEY-E connector are redefined. Since the NGFF KEY-E connector of electronic devices is usually used for the WiFi interface, the definition of pins is adapted to the specification of the WiFi interface. However, when the WiFi interface and the NGFF KEY-E connector are connected (for example, soldered together), some pins of the NGFF KEY-E connector are in an idle state which are not used by the WiFi interface. In an embodiment, the idle pins are redefined.

In an embodiment, since the I/O port (such as USB slots and LAN slots) of other specifications needs more power or bandwidth, the idle pins are redefined to make the NGFF KEY-E connector applicable to the I/O ports of other specifications. In an embodiment, some pins of the NGFF KEY-E connector are redefined to increase power, improve signal bandwidth, or improve the reset control, which is not limited herein.

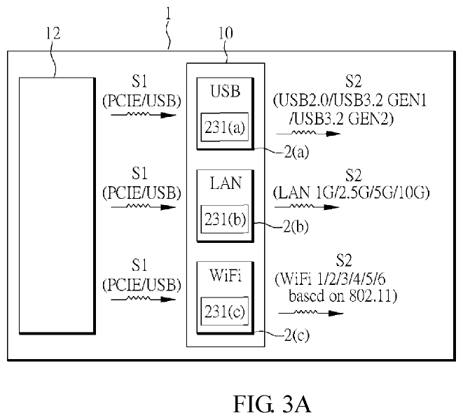

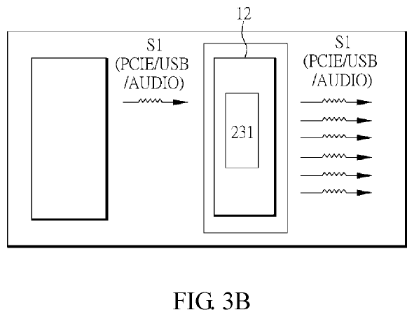

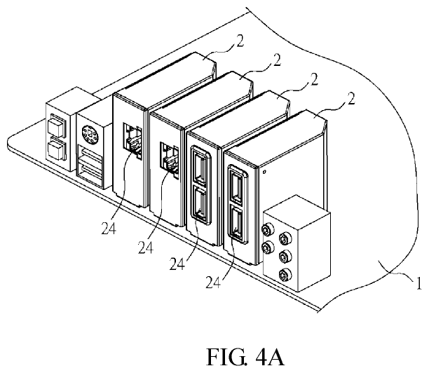

The detail of the control chip 231 is shown in FIG. 3A and FIG. 3B. Please also refer FIG. 1, FIG. 2A, FIG. 2B, and FIG. 2C.

FIG. 3A is a schematic diagram view showing an operation principle of the control chip 231 of the detachable module 2 according to an embodiment of the disclosure. In the embodiments, the detachable module 2 is a detachable module 2(a) of the USB specification, a detachable module 2(b) of the LAN specification, a detachable module 2(c) of the WiFi specification.

In an embodiment, the detachable module 2(a) of the USB specification includes a first control chip 231(a). The first control chip 231(a) has a signal converting function. In an embodiment, the signal converting function is achieved via circuits of the first control chip 231(a). The first control chip 231(a) is configured to convert an original signal S1 (a PCEI signal or a USB signal) from the signal transmitting terminal 12 to a specific specification signal S2 adapted to the I/O port 24. For example, the USB signal or the PCIe signal is converted to a USB2.0 signal, a USB3.0 (such as USB3.2 GEN1 and USB3.2 GEN2) signal or a USB signal of other generations, which is not limited herein. In an embodiment, the first control chip 231(a) is configured to convert external signals received at the I/O port 24 to the signal adapted to components (such as a CPU) on the motherboard 1.

In an embodiment, the detachable module 2(b) of the LAN specification includes a second control chip 231(b). The second control chip 231(b) includes the signal converting function. In an embodiment, the signal converting function is achieved via circuits of the second control chip 231(b). The second control chip 231(b) is configured to convert an original signal S1 from the signal transmitting terminal 12 to a specific specification signal S2 adapted to the I/O port 24. For example, the USB signal or the PCIe signal is converted to a specification of LAN 1G LAN 2.5G, LAN 5G or LAN 10G which is not limited herein. In an embodiment, the second control chip 231(b) is configured to convert external signals received at the I/O port 24 to the signal adapted to components (such as a CPU) on the motherboard 1.

In an embodiment, the detachable module 2(c) of the WiFi specification includes a third control chip 231(c). The third control chip 231(c) includes the signal converting function. In an embodiment, the signal converting function is achieved via circuits of the third control chip 231(c). The third control chip 231(c) is configured to convert an original signal S1 from the signal transmitting terminal 12 to a specific specification signal S2 adapted to the I/O port 24. For example, the USB signal or the PCIe signal is converted to a signal of the WiFi specification, such as the WiFi 1/2/3/4/5/6 specification (base on 802.11), which is not limited herein. In an embodiment, the second control chip 231(b) is configured to convert external signals received at the I/O port 24 into the signal adapted to components (such as a CPU) on the motherboard 1.

Since each connector 14 on the motherboard 1 support different connection specifications, each of the connectors 14 can be connected with different detachable modules 2. In the embodiment, the detachable module 2 has the same or different connection specification, which is not limited herein. In an embodiment, the I/O port 24 also can have other specifications, such as an audio signal plug, which is not limited herein.

In an embodiment, the control chip 231 has other types. FIG. 3B is a schematic diagram showing an operation principle of the control chip 231 of the detachable module 2 according to an embodiment of the disclosure. In an embodiment, the control chip 231 of the detachable module 2 includes a multiplexer function to receive the original signal S1 (such as the PCIe signal, the USB signal, or the audio signal) and output a plurality of original signals S1 (such as the PCIe signal, the USB signal, or the audio signal). In an embodiment, the multiplexer function of the control chip 231 is achieved via circuits, which is not limited herein.

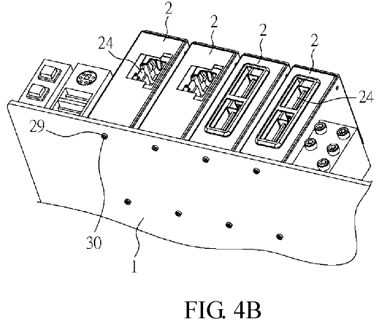

FIG. 4A is a side view showing the detachable module 2 is assembled to the motherboard 1 according to an embodiment of the disclosure. Please refer to FIG. 1 and FIG. 4, the detachable module 2 is easily assembled to or disassembled from the motherboard 1. When the I/O ports on the motherboard 1 does not meet the requirements of users, the detachable module 2 of the motherboard 1 can be replaced easily. As a result, the I/O ports are easily upgraded or replaced, which is very convenient.

FIG. 4B is a bottom view showing the detachable module 2 is assembled to the motherboard 1 according to an embodiment of the disclosure. As shown in FIG. 4B, the detachable module 2 and the motherboard 1 have corresponding fixing components, such as the screw holes 29 and the screws, which is not limited herein.

In sum, the detachable module in embodiments is easily replaced, when the connectors are failure or the connectors do not meet the requirements, the connectors can be regraded easily. Thus, the motherboard can be used more effectively.

Although the present disclosure has been described in considerable detail with reference to certain preferred embodiments thereof, the disclosure is not for limiting the scope of the disclosure. Persons having ordinary skill in the art may make various modifications and changes without departing from the scope. Therefore, the scope of the appended claims should not be limited to the description of the preferred embodiments described above.

What is claimed is:

1. A motherboard, comprising:
a signal transmitting terminal; and
a plurality of connectors, respectively connected to the signal transmitting terminal,
wherein each of the connectors supports a plurality of connection specifications and assembled as a detachable module, and the detachable module includes a golden finger connecting member and an input and output (I/O) port.

2. The motherboard according to claim 1, wherein the I/O port is a Universal Serial Bus (USB) I/O port, a Local Area Network (LAN) I/O port, a Wireless Fidelity (WiFi) I/O port, or an audio signal I/O port.

3. The motherboard according to claim 2, wherein the signal transmitting terminal is configured to transmit an original signal to the connectors, and the original signal is a USB signal or a PCIe signal.

4. The motherboard according to claim 3, wherein the detachable module includes a signal converter configured to convert the original signal to a specific specification signal for the I/O port.

5. The motherboard according to claim 1, wherein the connectors are next generation form factor (NGFF) connectors.

6. A detachable module, configured to be assembled at a motherboard, the motherboard includes a signal transmitting terminal and a plurality of connectors, the connectors are connected to the signal transmitting terminal, and each of the connectors supports a plurality of connection specifications for assembling a detachable module, the detachable module comprising:
a golden finger connecting member; and
an I/O port.

7. The detachable module according to claim 6, wherein the I/O port includes a USB I/O port, a LAN I/O port, a WiFi I/O port, or an audio signal I/O port.

8. The detachable module according to claim 7, wherein the signal transmitting terminal is configured to transmit an original signal to the connectors, and the original signal is a USB signal or a PCIe signal.

9. The detachable module according to claim 8, wherein the detachable module includes a signal converter configured to convert the original signal to a specific specification signal.

10. The detachable module according to claim 6, wherein the connectors are NGFF connectors.
